(19) United States
(12) Patent Application Publication
(10) Pub. No.: US 2017/0142838 A1
(43) Pub. Date: May 18, 2017

(54) LAMINATED THIN FILM CAPACITOR

(71) Applicant: Taiyo Yuden Co., Ltd., Tokyo (JP)

(72) Inventor: Masaru KUROSAWA, Tokyo (JP)

(21) Appl. No.: 15/332,399

(22) Filed: Oct. 24, 2016

(30) Foreign Application Priority Data
Nov. 16, 2015 (JP) 2015-224168
Aug. 12, 2016 (JP) 2015-158690

(51) Int. Cl. H05K 1/18; H01G 4/38; H01G 4/018; H01G 4/005; H01G 4/33; H01G 4/236

(52) U.S. Cl. CPC H05K 1/181; H01G 4/33; H01G 4/236; H01G 4/018; H01G 4/005; H01G 4/38; H05K 2201/10015

(57) ABSTRACT

One object is to provide a laminated thin film capacitor in which loss of capacitance and degradation of reliability due to structural damage are suppressed. The laminated thin film capacitor of the present invention includes: a plurality of thin film capacitors stacked together via a joining resin to form a laminate; and a first external electrode and a second external electrode electrically connected to the plurality of thin film capacitors, wherein each of the plurality of thin film capacitors includes: at least one MIM structure including a dielectric body, a first internal electrode disposed on one principal surface of the dielectric body, and a second internal electrode disposed on the other principal surface of the dielectric body; a first intermediate electrode electrically connecting the first internal electrode and the first external electrode; and a second intermediate electrode electrically connecting the second internal electrode and the second external electrode.

### CROSS-REFERENCE TO RELATED APPLICATIONS

This application is based on and claims the benefit of priority from Japanese Patent Application Serial Nos. 2015-224168 (filed on Nov. 16, 2015) and 2016-158690 (filed on Aug. 12, 2016), the contents of which are hereby incorporated by reference in their entirety.

### TECHNICAL FIELD

The present invention relates to a laminated thin film capacitor.

### BACKGROUND

As electronic devices are downsized, electronic components mounted on electronic substrates are also required to have a smaller size and thickness. In particular, capacitors are severely required to have a smaller size and thickness. However, multi-layer chip capacitors (MLCCs), the mainstream of capacitors, are made of ceramic and are so brittle as to be limited in reduction of thickness. To achieve super-thin capacitor devices that are difficult to make with MLCCs, thin film capacitors are being developed using thin film techniques.

In Japanese Patent Application Publication No. 2014-90077 (the “'077 Publication”), there is disclosed a conventional technique for forming, on a top surface of a device, connection between an internal electrode and an external electrode of a thin film capacitor.

In Japanese Patent Application Publication No. 2004-95641 (the “'641 Publication”), there is disclosed an example of a technique for withdrawing an internal electrode from a side surface of a device as with multi-layer chip capacitors (MLCCs), which was devised for suppressing reduction of capacitance producing unit.

In Japanese Patent No. 4674606 (the “'606 Publication”), there is disclosed a technique for forming a wiring pattern for connecting an internal electrode and an external electrode on the top surface of a thin film capacitor.

In Japanese Patent Application Publication No. 2012-39035 (the “'035 Publication”), there is disclosed an MLCC having multi-terminal electrode structure made of a conventional sintered ceramic body.

To increase the capacitance of a thin film capacitor, it is effective to form internal electrodes and dielectric bodies into a multi-layer structure. However, multiple thin films staked together are more subject to structural distortion due to accumulated stresses and tend to have more particles attached thereon during fabrication, and therefore, it was difficult to form such thin films without reduction in yield.

In the technique disclosed in the '077 Publication, a highly accurate processing is required and, an internal and external electrode-connecting region is formed at the cost of electrode crossing regions that produce capacitance, thus reducing the capacitance.

In the technique disclosed in the '641 Publication, internal electrodes can be exposed in the side surfaces by dieing, but it may be possible that internal electrodes having an extremely small thickness and dielectric bodies are damaged to lose electric characteristics and reliability thereof.

FIG. 1 of the '077 Publication shows an example of conventional laminated thin film capacitors. The laminated thin film capacitor shown in FIG. 1 include a capacitor portion 11 having electrodes and dielectric bodies stacked alternately on the substrate 1, a protection layer 12, an inner protection layer 13, and an outer protection layer 34. In the conventional technique, the electrodes and the dielectric bodies of thin films are stacked alternately, which caused the following defects.

(1) If a layer having poor characteristics is produced or a failure occurs in the course of processing, the entirety of the laminated structure may become defective. In addition, a layer having poor characteristics cannot be removed in the course of processing.
(2) To increase or decrease the number of stacked layers, it is necessary to prepare a number of masking sets for processing individually in accordance with the number of stacked layers.
(3) As a larger number of layers are stacked together, the thin film is warped due to accumulated stresses, resulting in reduced workability.
(4) As a larger number of layers are stacked together, the film surface of the top layer has larger unevenness that degrades characteristics of the thin film.
(5) Devices fabricated on a wafer need to be died for separation.

Thus, in the conventional technique, a thin film capacitor laminated for a larger capacitance needs to go through precise processing and have complex structure, resulting in a large processing load. In addition, if it is attempted to connect the internal electrodes and the external electrodes by a simple method, the reliability of the device is significantly degraded.

As disclosed in the '606 Publication, a typical method for connecting the internal electrodes and the external electrodes of a thin film capacitor was to form a wiring pattern on the top surface of a device. However, in this technique, a highly accurate processing is required, and an internal and external electrode-connecting region is formed at the cost of electrode crossing regions that produce capacitance, thus reducing the capacitance. Further, a capacitor having multi-terminal structure for reducing equivalent series inductance (ESL) has significantly reduced effective area that achieves less benefit of lamination.

Further, although an effective way to increase the capacitance of a thin film capacitor is to laminate the internal electrode and the dielectric layer, a laminated thin film including multiple layers tends to have distorted structure due to accumulated internal stresses and degraded characteristics due to attached particles. Therefore, it was difficult to form multi-layer structure without reducing the yield. In addition, as disclosed in the '035 Publication, it is also attempted to redesign conventional MLCCs including sintered ceramic body to have multi-terminal electrode structure. However, in view of the strength of the material, it is difficult to provide the devices with lower profiles equal to or less than 90 μm.

### SUMMARY

The present invention is intended to overcome these problems; and an object of the invention is to improve the fabrication method and structure of super low-profile capacitors using thin film techniques.

To overcome the above problem, the present invention provides a laminated thin film capacitor comprising: a plurality of thin film capacitors stacked together via a joining resin to form a laminate; and a first external electrode and a second external electrode electrically connected to the plurality of thin film capacitors, wherein each of the plurality of thin film capacitors includes: at least one MIM structure including a dielectric body, a first internal electrode disposed on one principal surface of the dielectric body, and a second internal electrode disposed on the other principal surface of the dielectric body; a first intermediate electrode electrically connecting the first internal electrode and the first external electrode; and a second intermediate electrode electrically connecting the second internal electrode and the second external electrode.

The laminated thin film capacitor may also be configured such that the plurality of thin film capacitors are electrically connected to each other via a first connection electrode and a second connection electrode extending through the laminate, each of the plurality of thin film capacitors has the first intermediate electrode thereof electrically connected to the first connection electrode, each of the plurality of thin film capacitors has the second intermediate electrode thereof electrically connected to the second connection electrode, the first external conductor is electrically connected to the first connection electrode at an outermost layer of the laminate, and the second external conductor is electrically connected to the second connection electrode at the outermost layer of the laminate.

The laminated thin film capacitor may preferably be configured such that the first connection electrode and the second connection electrode are formed substantially in parallel with each other along a lamination direction of the laminate.

The laminated thin film capacitor may also be configured such that each of the plurality of thin film capacitors further includes a protective film disposed to cover the MIM structure, the first intermediate electrode extends from the first internal electrode through the protective film to an interface between the protective film and the joining resin and extends along the interface toward one end surface of the thin film capacitor so as to be electrically connected to the first external electrode, the second intermediate electrode extends from the second internal electrode through the protective film to an interface between the protective film and the joining resin and extends along the interface toward the other end surface of the thin film capacitor so as to be electrically connected to the second external electrode.

The laminated thin film capacitor may also be configured such that each of the plurality of thin film capacitors further includes a protective film disposed to cover the MIM structure, the first intermediate electrode extends from the first internal electrode through the protective film to an interface between the protective film and the joining resin and extends along the interface toward one end surface of the thin film capacitor so as to be electrically connected to the first connection electrode, the second intermediate electrode extends from the second internal electrode through the protective film to an interface between the protective film and the joining resin and extends along the interface toward the other end surface of the thin film capacitor so as to be electrically connected to the second connection electrode.

The laminated thin film capacitor may preferably configured such that the first intermediate electrode and the second intermediate electrode extend to the interface with the same joining resin.

The laminated thin film capacitor may also be configured such that the first intermediate electrode is exposed from one end surface of the protective film, and the second intermediate electrode is exposed from the other end surface of the protective film.

The laminated thin film capacitor may preferably be configured such that the joining resin covers at least a part of a surface of the protective film other than a part covered with the first external electrode and the second external electrode.

The laminated thin film capacitor may preferably be configured such that each of the plurality of thin film capacitors has directionality caused by an internal structure thereof being asymmetric in a lamination direction, and the laminate includes an even number of thin film capacitors constituted by a same number of positively oriented ones and oppositely oriented ones.

The laminated thin film capacitor may also be configured such that each of the plurality of thin film capacitors has directionality caused by an internal structure thereof being asymmetric in a lamination direction, and the laminate includes one thin film capacitor and an even number of thin film capacitors constituted by a same number of positively oriented ones and oppositely oriented ones.

The laminated thin film capacitor may also be configured such that at least one or neither principal surface of the laminated thin film capacitor has a supporting substrate.

The present invention also provides a circuit comprising: a mounting surface; first and second wiring provided on the mounting surface; and the laminated thin film capacitor mounted on the mounting surface, wherein the first and second external conductors of the laminated thin film capacitors are electrically connected to the first and second wiring, respectively.

The present invention also provides a printed circuit board including the laminated thin film capacitor mounted thereon.

According to the present invention, a laminated thin film capacitor can be fabricated without need of complex operation and without degradation of reliability.

### BRIEF DESCRIPTION OF THE DRAWINGS

FIG. 1 is a schematic sectional view of a laminated thin film capacitor according to the present invention.

FIG. 2 is a schematic sectional view of a thin film capacitor having a joining resin formed thereon.

FIG. 3 is a schematic sectional view showing a workflow of fabricating the thin film capacitor having a joining resin formed thereon.

FIG. 4 is a plain view of the thin film capacitor.

FIG. 5 is a plain view of the thin film capacitor having a joining resin formed thereon.

FIG. 6 is a schematic sectional view showing a joining operation of the thin film capacitor.

FIG. 7 is a schematic sectional view showing a removing operation of the joined laminated capacitor.

FIG. 8 is a schematic sectional view of the laminated thin film capacitor having external electrodes formed on one principal surface thereof.

FIG. 9 is a schematic external view of the laminated thin film capacitor having external electrodes formed on one principal surface thereof.

FIG. 10 is a schematic sectional view of the laminated thin film capacitor after a transferring operation.

FIG. 11 is a schematic external view of the laminated thin film capacitor after the transferring operation.

FIG. 12 is a schematic sectional view of the laminated thin film capacitor having external electrodes formed on the other principal surface thereof.

FIG. 13 is a schematic external view of the laminated thin film capacitor having external electrodes formed on the other principal surface thereof.

FIG. 14 is a schematic section view showing examples of lamination operation.

FIG. 15 is a schematic external view of a wafer according to the present invention.

FIG. 16 is a schematic sectional view showing a removing operation of the laminated thin film capacitor after the external electrodes are formed on the other principal surface thereof.

FIG. 17 is a schematic external view of an example of circuit board having the laminated thin film capacitor of the present invention mounted thereon.

FIG. 18 is a sectional view of a laminated thin film capacitor according to the second embodiment of the present invention.

FIG. 19 is an external perspective view of the laminated thin film capacitor.

FIG. 20 is a sectional view of a MIM structure.

FIG. 21 shows a plain view and a sectional view for explaining a fabrication process of the thin film capacitor.

FIG. 22 shows a plain view and a sectional view for further explaining the fabrication process of the thin film capacitor.

FIG. 23 shows a plain view and a sectional view for further explaining the fabrication process of the thin film capacitor.

FIG. 24 shows a plain view and a sectional view for further explaining the fabrication process of the thin film capacitor.

FIG. 25 shows a plain view and a sectional view for further explaining the fabrication process of the thin film capacitor.

FIG. 26 shows a plain view and a sectional view for further explaining the fabrication process of the thin film capacitor.

FIG. 27 shows a plain view and a sectional view for further explaining the fabrication process of the thin film capacitor.

FIG. 28 shows a plain view and a sectional view for further explaining the fabrication process of the thin film capacitor.

FIG. 29 shows a plain view and a sectional view for further explaining the fabrication process of the thin film capacitor.

FIG. 30 is a sectional view for explaining a method of joining the thin film capacitors.

FIG. 31 is a sectional view showing an example of the laminated thin film capacitor having multi-terminal electrode structure on one surface thereof.

FIG. 32 is a sectional view showing an example of the laminated thin film capacitor having multi-terminal electrode structure on both surfaces thereof.

### DESCRIPTION OF EXAMPLE EMBODIMENTS

The terms used herein are defined as follows. The term “MIM structure” refers to a member including a dielectric body, a first internal electrode disposed on one of the principal surfaces of the dielectric body, and a second internal electrode disposed on the other of the principal surfaces of the dielectric body. A plurality of MIM structures may be stacked together. When a plurality of MIM structures are stacked together, the first (second) internal electrode of one MIM structure can also serve as the second (first) internal electrode of another MIM structure. The term “thin film capacitor” refers to a member including: at least one MIM structure including a dielectric body, a first internal electrode disposed on one of the principal surfaces of the dielectric body, and a second internal electrode disposed on the other of the principal surfaces of the dielectric body; a first intermediate electrode for electrically connecting the first internal electrode and a first external electrode (or a first external conductor); and a second intermediate electrode for electrically connecting the second internal electrode and a second external electrode (or a second external conductor). The term “protective film” or “protective layer” refers to an insulating member arranged to cover the MIM structure. The term “first protective film” refers to a member which is arranged to cover the MIM structure and through which the first and second intermediate electrodes extend. The term “second protective film” refers to a part of the protective film other than the first protective film. The protective film includes the first protective film and optionally includes the second protective film. The term “end surfaces of the protective film” refers to side surfaces of the protective film other than the principal surfaces. The term “connection electrode” refers to a conductive structure electrically connected to another connection electrode via intermediate electrodes in multi-layer thin film capacitors. The first internal electrode, the first intermediate electrode, and the first external electrode (the first external conductor and/or a first connection electrode) are electrically connected. Likewise, the second internal electrode, the second intermediate electrode, and the second external electrode (the second external conductor and/or a second connection electrode) are electrically connected. The first electrode group including the first external electrode, the first external conductor or the first connection electrode and the second electrode group including the second external electrode, the second external conductor or the second connection electrode have different polarities and are electrically insulated from each other at least with respect to direct current resistance components.

In the present invention, the thin film capacitors are stacked together by joining and removing techniques, and a structural feature is provided in the connection between the internal electrodes and the external electrodes. As a result, a laminated thin film capacitor can be fabricated without need of complex operation and without degradation of reliability.

Also, the thin film capacitors can be joined to each other with a joining resin, and the joining resin can be previously patterned to form gaps therein, so as to facilitate formation of electrical connection between the internal electrodes and the external electrodes. In this technique, the thin film capacitor can be laminated without loss of capacitance or degradation of reliability due to structural damage.

Further, the thin film capacitor can be low-profile with a thickness of 100 μm or smaller, which is hardly achievable for MLCCs.

Additionally, in the present invention, the capacitance value can be readily adjusted by repeating the joining and removing operations of the thin film capacitor for a required number of times. In other words, the capacitance can be varied with the number of units stacked together, allowing easy adjustment.

Further, in the technique of the present invention, the thin film capacitors may be stacked together to produce the following advantages.

(1) Since the thin film capacitors having confirmed excellent characteristics are stacked together, there is less possibility that the yield is reduced due to defects in the MIM structures.
(2) Since the number of stacked MIM structures can be small (e.g., one or two), less defects as observed in conventional techniques may occur due to increase in the number of the MIM structures.
(3) Since the devices repeatedly removed and joined are patterned, separation (dieing) is unnecessary. Since the devices are not died, the intervals between the devices can be smaller than in conventional techniques, thus increasing the number of obtainable capacitors.

The laminated thin film capacitor fabricated by the method according to the present invention can be directly joined to (mounted on) a Si interposer substrate or a semiconductor device, not only applied to a unitary component. This may enable reducing the load of mounting operation and reducing the parasitic component in electrical characteristics caused by wiring.

With the laminated thin film capacitors according to the present invention, even in constructing multi-terminal electrode structure for reducing equivalent series inductance (ESL), thin film capacitors having similar capacitances can be stacked together to increase the capacitance efficiently. Also, the contact resistance between the electrodes in the laminate can be reduced, resulting in smaller equivalent series resistance (ESR). With the laminated thin film capacitors according to the present invention, if the thin film capacitors have almost the same capacitance (with variation of ±5% or smaller), the self-resonant frequency may have a sharp waveform, not a multi-stage waveform, producing stable characteristics.

Embodiments of the present invention will now be described in more details with reference to the attached drawings.

### First Embodiment

FIG. 2 shows the thin film capacitor of the present invention. The thin film capacitor may include: at least one MIM structure including a dielectric body 104, a first internal electrode 103 disposed on one of the principal surfaces of the dielectric body, and a second internal electrode 105 disposed on the other of the principal surfaces of the dielectric body; a first intermediate electrode 107a for electrically connecting the first internal electrode 103 and a first external electrode (not shown); and a second intermediate electrode 107b for electrically connecting the second internal electrode 105 and a second external electrode (not shown). FIG. 2 shows only one MIM structure, but a plurality of MIM structures may be stacked together. When a plurality of MIM structures are stacked together, an internal electrode of one MIM structure can also serve as an internal electrode of another MIM structure. The thin film capacitor may further include protective films 102, 106 that are disposed to cover the MIM structure, and the intermediate electrodes 107a, 107b may extend through the protective films 102. FIG. 2 shows that the thin film capacitor may be formed on the supporting substrate 100 via a removal layer 101, and a joining resin 108 may be formed on the first protective film 106. The intermediate electrodes 107a, 107b may extend through the first protective film 106 to the interface between the first protective film 106 and the joining resin 108 and further extend along the interface toward one of the end surfaces of the thin film capacitor. The intermediate electrodes 107a, 107b, extending through the first protective film 106, may extend to either the interfaces with different joining resins 108 or the interface with the same joining resin 108. FIG. 2 shows that the intermediate electrodes 107 are exposed from the end surfaces of the protective films 102, 106, but this is not essential. The intermediate electrodes 107a, 107b may preferably be exposed from the end surfaces of the protective films. A plurality of thin film capacitors may be fabricated on the supporting substrates 100, and these thin film capacitors may be joined to each other with a joining technique and removed from one of the supporting substrates 100.

These joining and removing operations may be repeated for a required number of times to fabricate a laminated thin film capacitor having a desired number of stacked layers.

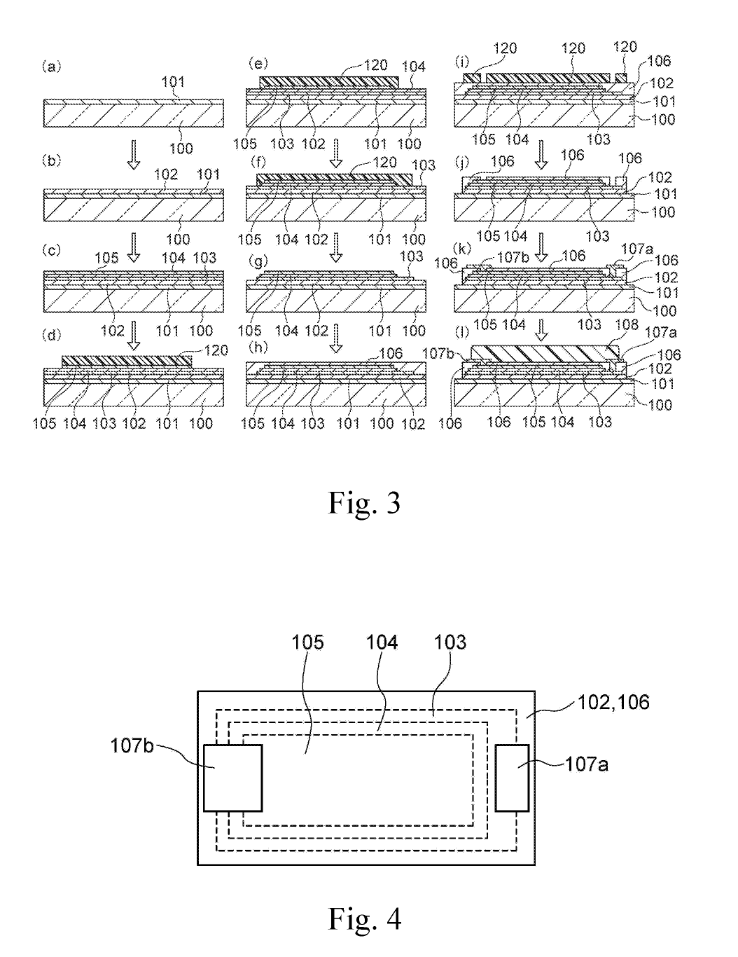

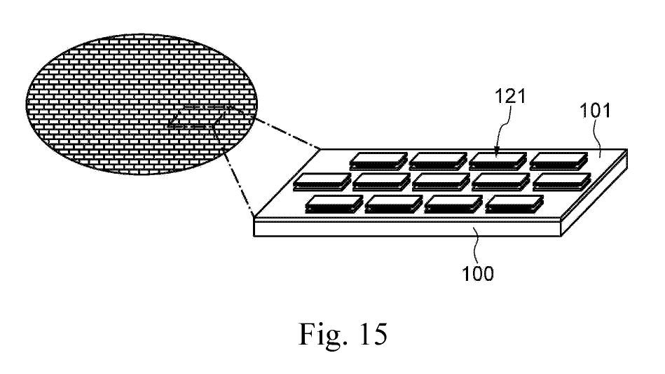

FIG. 3 shows a workflow of fabricating the thin film capacitor of the present invention. As shown in FIG. 15, a plurality of thin film capacitors may typically be fabricated on the supporting substrate 100 in a lump. The supporting substrate, which may be selected in consideration of the following removing operation, may suitably have a high smoothness and a heat resistance against the heat imparted during the capacitor fabricating operation. If laser removal is employed in the removing operation, substrates that transmit laser such as sapphire or quartz may be suitable. For methods other than laser removal, substrates like Si are desirable.

FIG. 3(a)

A removal layer 101 may be formed on the supporting substrate 100. The material for the removal layer 101 may vary depending on the following removing method. For laser removal, a material that can be burned away by laser application (metals or oxides) may be selected; and for the case where the removal layer 101 will be eliminated by wet etching, a material that can serve as a sacrifice layer (to be eliminated later) may be selected.

FIG. 3(b)

The second protective film 102 may be formed on the removal layer 101. The material for the second protective film 102 may be either inorganic or organic, but may be required to have heat resistance for the following capacitor forming process, to be robust enough not to be damaged in the removing operation, and to ensure the reliability of the completed capacitor. Applicable inorganic materials may include SiO₂, SiN, Al₂O₃, and ZrO₂, and applicable organic materials may include polyimide resins and benzocyclobutene (BCB) resins. The material has to be shaped to such a thickness that achieves a desired ability, and the thickness may preferably be 4 μm or smaller, or more preferably 1 μm or smaller. If the MIM structure is safe from damage in the removing operation, the second protective layer may not be formed. As will be described later, the second protective layer 102 may not be formed depending on the lamination state of the completed laminated thin film capacitor.

FIGS. 3(c) to 3(g)

The MIM structure may be formed of the first and second internal electrodes 103, 105 and the dielectric body 104. In the drawing, one dielectric body 104, the first internal electrode 103 disposed on one of the principal surfaces of the dielectric body, and the second internal electrode 105 disposed on the other of the principal surfaces of the dielectric body may be formed in a lump and shaped desirably by resist patterning. The capacitor may also be formed by unlimited methods other than the above lump formation. The capacitors may be worked by dry etching, wet etching, etc. Alternatively, metal masking may be used. The electrode material for the internal electrodes 103, 105 and the dielectric material for the dielectric body 104 may not be particularly limited. Typically, the electrode material may be Pt, Ni, Pd, Cu, Al, etc., and the dielectric material may be barium strontium titanate (BST), barium titanate (BT), strontium titanate (ST), Al₂O₃, ZrO₂, or other metal oxides. To obtain a capacitor having a large capacitance with a small number of times of stacking, it may be preferable to use a material having a large relative dielectric constant such as BST, BT, and ST. To obtain a capacitor having excellent temperature characteristics and DC bias characteristics, it may be preferable to use a paraelectric material having relatively low relative dielectric constant such as Al₂O₃, ZrO₂, and HfO₂. The electrode material may preferably be those having a large work function such as Ni and Pt for reducing the leakage current value. Further, if, e.g., a sputtering apparatus is used and BST is used as a dielectric material, the films may be formed at a high temperature of 600° C. or higher and in an oxygen atmosphere, and therefore, Pt is preferable because it is less subject to oxidation. Accordingly, usable electrodes may be different depending on the atmosphere for forming the dielectric body. If the dielectric body is formed at a low temperature such as about 150° C. or 200° C. using atomic layer deposition (ALD), then Ni, Al, Cu, etc. can also be applied instead of Pt which is expensive. FIGS. 3(c) to (g) show the case where only one MIM structure is used. As described above, the thin film capacitor may also include a plurality of MIM structures. Further, these operations may be repeated to fabricate a laminated thin film capacitor including a larger number of thin film capacitors stacked together. When a plurality of MIM structures are stacked together, an internal electrode of one MIM structure can also serve as an internal electrode of another MIM structure.

FIGS. 3(h) to 3(j)

The first protective film 106 may be formed. The material for the first protective film 106 may be selected in the same manner as the second protective film 102, but the constraint therefor can be relieved because it does not go through the capacitor forming process. However, the first protective film 106 may preferably be formed of the same material as the second protective film 102 because, if so, the capacitor can be covered with the films having the same mechanical behavior such as coefficient of thermal contraction. The first protective film 106 may have openings formed therein for connection with the internal electrodes 103, 105. If the first protective film 106 is formed of an inorganic material, it may be suitable to work the first protective film by dry etching with resist patterning. If the first protective film 106 is formed of an organic material, patterning with photosensitive material may be used to reduce the processing load. The part of the protective film formed between adjacent thin film capacitors on the substrate may be unnecessary and thus can be removed when the openings are formed, such that separation of the capacitors can be omitted if the supporting substrate is removed in the later operation.

FIG. 3(k)

The intermediate electrodes 107a, 107b may be formed. The intermediate electrodes 107a, 107b may form electrical connection with the internal electrodes 103, 105 through the openings in the first protective film 106. The intermediate electrodes 107a, 107b may be formed so as to extend on the first protective film 106 toward the end surfaces of the thin film capacitor. The intermediate electrodes 107a, 107b may preferably be exposed from the end surfaces of the protective films. FIG. 4 is a view from upside of FIG. 3(k). The second protective film 102 and the MIM structure 103, 104, 105 may be under the first protective film 106, and the intermediate electrodes 107a, 107b may appear from the surface of the first protective film 106. The electrode material and working method for the intermediate electrodes 107a, 107b may be as described for the internal electrodes 103, 105. In the following description, the “intermediate electrodes 107” may represent the two intermediate electrodes for simplicity.

FIG. 3(l)

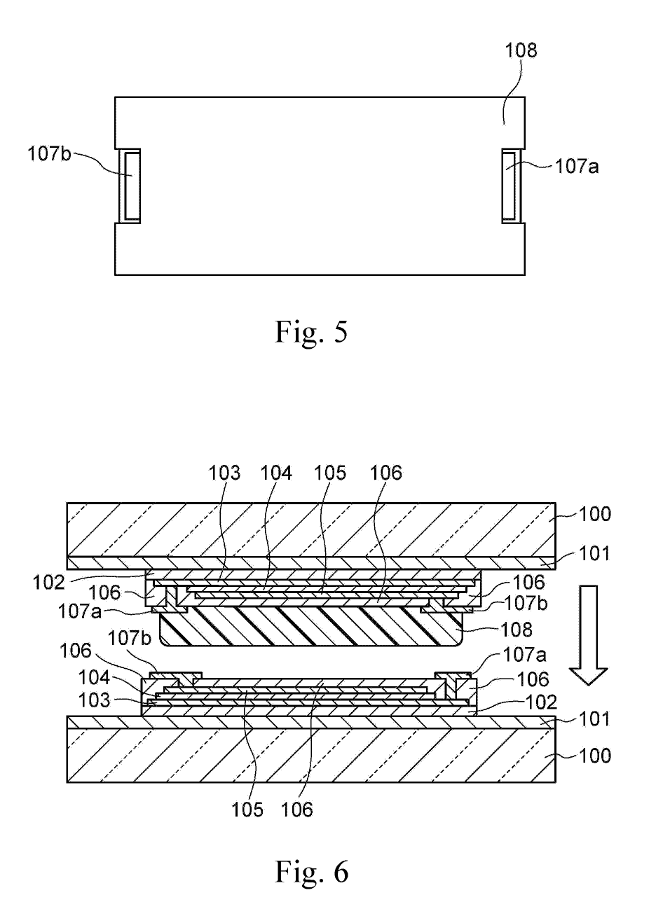

The joining resin 108 may be patterned. First, a photosensitive resin made of phenol-based polymer, polyimide, BCB, etc. may be used to form an uncured joining resin 108 on the first protective film 106 of the thin film capacitor. Then, the joining resin may be patterned so as not to cover at least a part of the regions of the intermediate electrodes 107 that form connection with the external electrodes 109a, 109b serving as external conductors. FIG. 5 shows an example pattern. The shape of the pattern may also be configured such that other part of the region of the first protective film 106 is not covered with the joining resin 108. The type of light (the type of light source) used in the lithographic operation for patterning may be appropriately selected from semiconductor laser, G-line, H-line, and I-line of a high-pressure mercury-vapor lamp, KrF excimer laser, ArF excimer laser, F2 excimer laser, metal halide lamp, ultraviolet rays, extreme ultraviolet rays, electron beam, etc. In the following description, the “external electrodes 109” may represent the two external electrodes for simplicity.

The joining resin 108 may be required to have such a thickness as to satisfy the requirement for the joining operation, and the thickness may preferably be 5 μm or smaller, or more preferably 2 μm or smaller for lower profiles. In curing the resin used as the joining resin 108, the degree of curing may be adjusted in accordance with the type and characteristics of the resin so as to ensure the tight adhesion in the following joining operation. For example, the curing may be stopped at the so-called B-stage state, or the semicured state where the resin has no tack and is apparently cured (an intermediate stage of the reaction of thermosetting resins where the material is softened and expanded by heating but does not completely melt or dissolve upon contact with a certain kind of liquid).

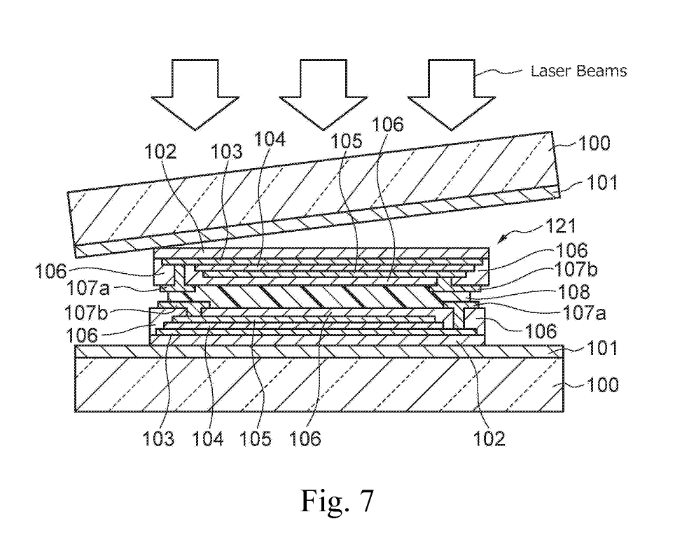

Next, the joining operation will now be described. The joining operation may be performed with the resin joining technique. As shown in FIG. 2, at least one of the thin film capacitors to be joined together may be previously provided with a photosensitive joining resin 108 patterned on the first protective film 106 thereof. FIG. 6 shows the joining operation in the present invention. A laminated capacitor may be obtained by stacking together the thin film capacitors such that the joining resin 108 of one of the thin film capacitors is in surface contact with the first protective film 106 of the other. After joining, the laminated capacitor may be baked as necessary for complete curing of the resin. FIG. 6 shows an example joining operation where one of the thin film capacitors has the joining resin 108 formed thereon. It is natural that both of the thin film capacitors to be joined may have the joining resin. FIG. 7 shows a joined laminated capacitor 121 after the joining operation. As shown, the joining resin 108 may cover at least part of the surface of the protective film other than the part to be covered with the first external electrode and the second external electrode. However, the intermediate electrodes may not necessarily be exposed from the end surfaces of the protective film. The intermediate electrodes may preferably be exposed from the end surfaces but may not be exposed from the side surfaces depending on the forming operation of the joining resin and the joining operation.

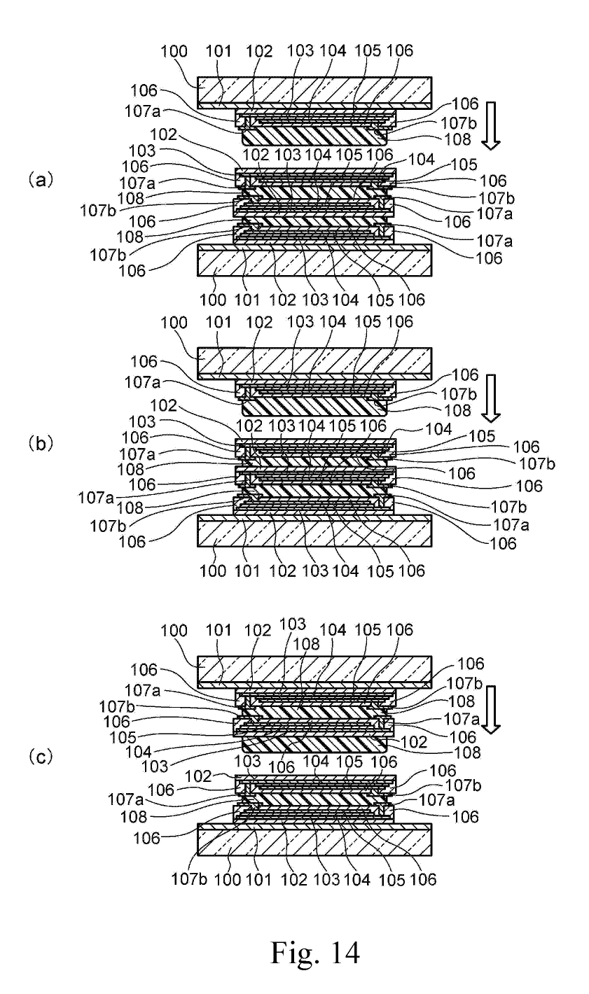

Next, the removing operation will now be described. As shown in FIG. 7, only one of the supporting substrates may be removed from the joined laminated capacitor 121 by laser application, etc. FIG. 6 shows joining of only two thin film capacitors, but a larger number of thin film capacitors can be stacked together by repeating the joining and removing operations in accordance with the required capacitance. In repeating the joining and removing operations to increase the number of thin film capacitors stacked together, the direction of stacking the thin film capacitors can be desirably changed by appropriately selecting the supporting substrate to be removed from among the two supporting substrates on each joining operation. The thin film capacitors may preferably be stacked together in a symmetrical arrangement with respect to the direction of stacking of the thin film capacitors such that less warp occurs due to stresses. In other words, the thin film capacitors may have directionality since the internal structure thereof is asymmetric in the direction of stacking, and the symmetrical arrangement may include an even number of thin film capacitors constituted by the same number of positively oriented ones and oppositely oriented ones (if an even number of thin film capacitors are stacked together), or the symmetrical arrangement may include one thin film capacitor and an even number of thin film capacitors constituted by the same number of positively oriented ones and oppositely oriented ones (if an odd number of thin film capacitors are stacked together). The asymmetry of the internal structure may be caused by the structure of the MIM structure and the intermediate electrodes 107 included in the thin film capacitor of the present invention, that is, the directionality caused by the structure of the intermediate electrodes 107 that may extend to only one of the principal surfaces of the thin film capacitor, and the directionality of the MIM structure from the second internal electrode 105 through the dielectric body 104 to the first internal electrode 103. FIGS. 14(a) to 14(c) show example operations of stacking multiple thin film capacitors together. In the drawings, an additional thin film capacitor with the joining resin 108 fabricated by the workflow shown in FIG. 3 may be stacked on the second protective film 102 of the joined laminated capacitor having the supporting substrate thereon removed, such that the joining resin 108 of the additional thin film capacitor is in surface contact with the second protective film 102. FIG. 14(a) shows an embodiment where supporting substrates on alternate sides are removed, FIG. 14(b) shows an embodiment where supporting substrates of the additional thin film capacitors are removed, and FIG. 14(c) shows a variation embodiment of the present invention where the second protective films 102 of the laminated thin film capacitors fabricated in the embodiment of the present invention are joined to each other. In other words, FIG. 14(a) involves the following operations. First, two thin film capacitors may be stacked together via the joining resin 108 such that the respective first protective films 106 are opposed to each other, and then the supporting substrate 100 of one of these two thin film capacitors may be removed, as shown in FIG. 7. An additional thin film capacitor may be stacked such that the first protective film 106 thereof is opposed to the second protective film 102 of the one of the two thin film capacitors having the supporting substrate thereof removed. Then, the supporting substrate 100 of the other thin film capacitor may be removed. Further, another additional thin film capacitor may be stacked such that the first protective film 106 thereof is opposed to the second protective film 102 of the other thin film capacitor having the supporting substrate thereof removed. FIG. 14 (b) involves the following operations. First, two thin film capacitors may be stacked together via the joining resin 108 such that the respective first protective films 106 are opposed to each other, and then the supporting substrate 100 of one of these two thin film capacitors may be removed, as shown in FIG. 7. An additional thin film capacitor may be stacked such that the first protective film 106 thereof is opposed to the second protective film 102 of the one of the two thin film capacitors having the supporting substrate thereof removed. Then, the supporting substrate 100 of the additional thin film capacitor may be removed. Further, another additional thin film capacitor may be stacked such that the first protective film 106 thereof is opposed to the second protective film 102 of the additional thin film capacitor having the supporting substrate thereof removed. FIG. 14 (c) involves the following operations. First, two thin film capacitors may be stacked together via the joining resin 108 such that the respective first protective films 106 are opposed to each other, and then the supporting substrate 100 of one of these two thin film capacitors may be removed, as shown in FIG. 7. Two such laminated thin film capacitors each including two stacked thin film capacitors one of which has the supporting substrate thereof removed may be prepared. At least one of these two laminated thin film capacitors may have the joining resin 108 patterned on the second protective film 102 of the thin film capacitor having the supporting substrate thereof removed, and the two laminated thin film capacitors may be stacked together via the joining resin 108 such that the respective second protective films 102 are opposed to each other. In combining this embodiment, the joining resin provided on the second protective film 102 can be appropriately selected, or even the second protective films 102 can be directly joined to each other without use of the joining resin, depending on the material of the second protective films 102.

A laminated thin film capacitor can be fabricated by repeating the joining and removing operations of the thin film capacitors. The supporting substrates of the thin film capacitors at both ends of the laminate may not necessarily be removed. If the supporting substrates remain unremoved, it may be preferable that a sacrifice layer or a removal layer is not formed on the supporting substrates. In this case, the supporting substrates may be died for separation and the external electrodes may be formed by dipping, as in conventional laminate processing. If the supporting substrates remain unremoved, the low profiles of the components cannot be achieved, but on the other hand, the component can have increased strength.

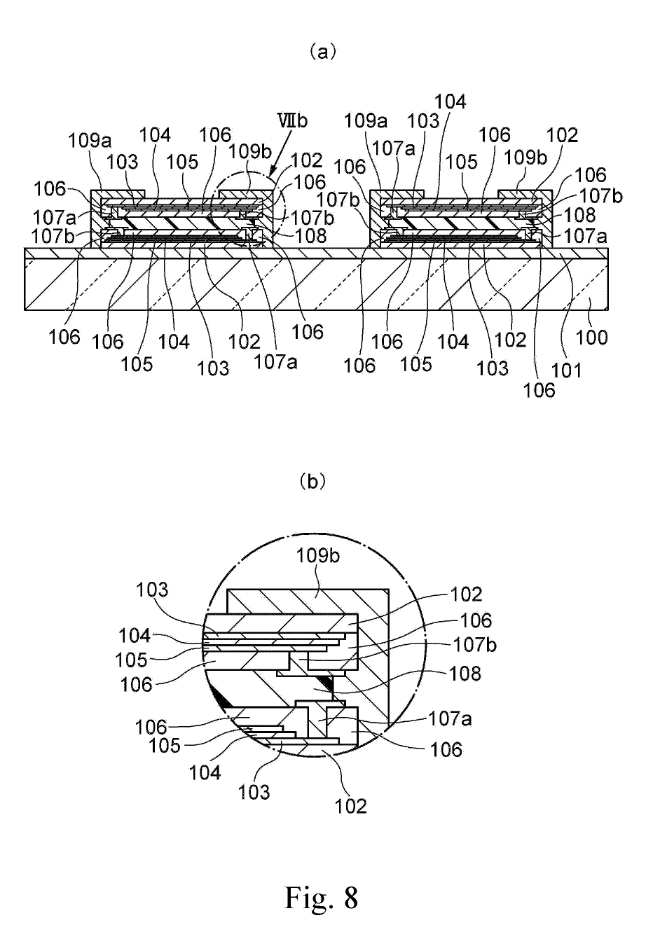

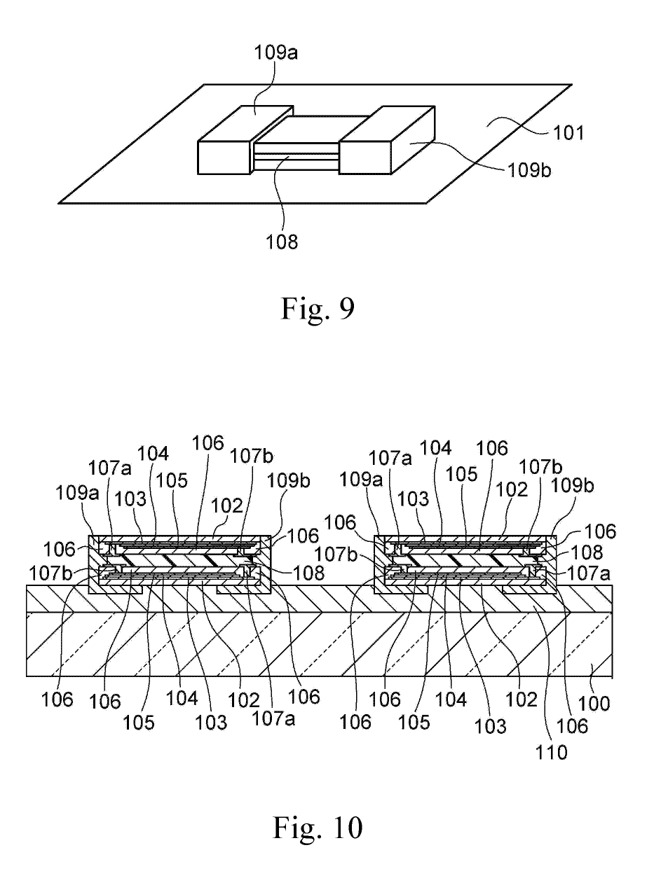

Next, the operation to form the external electrodes will now be described. The external electrodes may be formed so as to form electrical connection with each of the intermediate electrodes of the thin film capacitors in the joined laminated capacitor having one of the two supporting substrates thereof removed. As shown in FIG. 8(b), the intermediate electrodes 107 may extend to the gap containing the joining resin 108 and onto the first protective films 106. Therefore, an electrically conductive paste may be applied using a vacuum printer, etc. such that the paste enters the gap containing the joining resin 108 to form connection with the intermediate electrodes 107. Then, the paste may be cured to form a first and second external electrodes 109 on one of the principal surfaces of the joined laminated capacitor 121 shown in FIG. 8(a) and FIG. 9, and the supporting substrate on the other principal surface may be removed by laser application, etc. so as to complete a product (laminated thin film capacitor) with electrodes on one surface. The process of forming the external electrodes is not particularly limited but may use a vacuum process apparatus for sputtering, chemical vapor deposition (CVD), atomic layer deposition (ALD), etc.

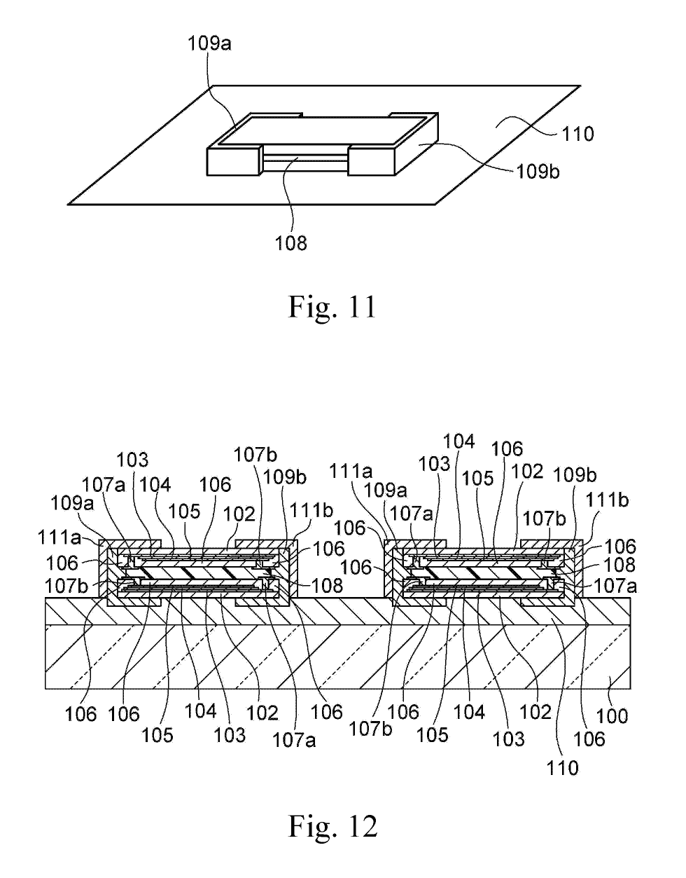

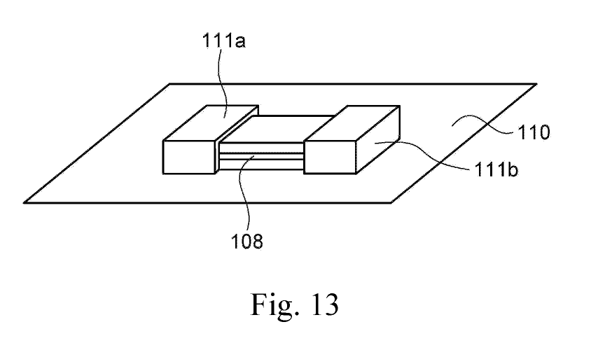

At the stage shown in FIGS. 8 and 9, the first and second external electrodes 109 may be formed on the principal surface of the joined laminated capacitor 121 from which a supporting substrate has been removed. It may also be possible that this joined laminated capacitor is transferred onto a removable substrate such as a UV-removable tape 110 and the process for forming the external electrodes is performed, so as to form the first and second external electrodes 111 on the other principal surface as shown in FIGS. 12 and 13. The first operation of this method may be to transfer the laminated thin film capacitor having the first and second external electrodes 109 formed on one principal surface thereof, onto a supporting substrate 100 having a UV-removable tape 110, etc. pasted thereon (FIGS. 10 and 11). This transfer may cause the other principal surface having no external electrodes applied thereto to be exposed. A metal paste may be applied onto the joined laminated capacitor again using the vacuum printer, etc. so as to form first and second external electrodes 111 on the other principal surface. These first and second external electrodes 111 may be connected with the first and second external electrodes 109 previously applied, at the side of the joined laminated capacitor 121. Since the external electrodes formed by the first and second application operations may form electrical connection at the side of the joined laminated capacitor, the laminated thin film capacitor may have electrodes on six surfaces thereof. The shape of the external electrodes may be various as long as each of the internal electrodes of the thin film capacitors is drawn outside via an intermediate electrode.

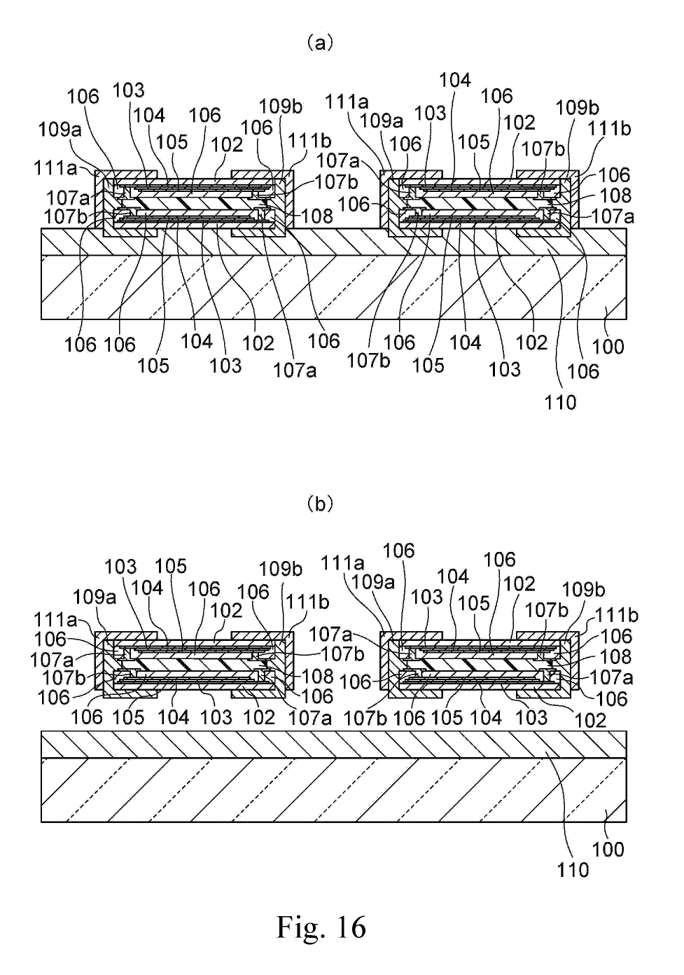

FIG. 16 is a schematic sectional view showing a removing operation of the laminated thin film capacitor after the external electrodes are formed as shown in FIGS. 12 and 13. More specifically, after the external electrodes 111 are formed as shown in FIGS. 12 and 13, the laminated thin film capacitor may be removed by laser application, etc. This may enable removal of the laminated thin film capacitor without need of separation by dieing as practiced conventionally, allowing smaller intervals between devices being fabricated and increasing the number of obtainable capacitors. Also, a laminated thin film capacitor in which loss of capacitance and degradation of reliability due to structural damage are suppressed can be fabricated. The same advantages can naturally be expected in the operation of removing the supporting substrate after the external electrodes are formed on one principal surface as shown in FIG. 8(a) and FIG. 9. Further, the yield can be further improved by performing “an operation of inspecting the capacitance of MIM capacitors and feeding only those having a predetermined capacitance into a subsequent operation” after any operation in the method of the present invention. The laminated thin film capacitor of the present invention can be finally removed from the supporting substrates. With no supporting substrates, the laminated thin film capacitors can be mounted with low profiles without discriminating the top and bottom surfaces of the device. In the present invention, it may also be possible that one or both of the supporting substrates of the thin film capacitors at both ends of the laminate remain unremoved. If the supporting substrates remain unremoved, the low profiles of the components cannot be achieved, but on the other hand, the component can have increased strength.

Next, a laminated thin film capacitor completed through the fabrication operations of the present invention will now be described.

FIGS. 8, 9, 12, and 13 are schematic external views showing an aspect of the laminated thin film capacitor having external electrodes formed on one or both principal surfaces thereof.

Each of the thin film capacitors in the laminated thin film capacitor of the present invention may include: at least one MIM structure including a dielectric body 104, a first internal electrode 103 disposed on one of the principal surfaces of the dielectric body, and a second internal electrode 105 disposed on the other of the principal surfaces of the dielectric body; an intermediate electrode 107a for electrically connecting the first internal electrode 103 and external electrodes 109b, 111b; and an intermediate electrode 107b for electrically connecting the second internal electrode 105 and the external electrodes 109a, 111a. The thin film capacitor may further include protective films 102, 106 that are disposed to cover the MIM structure and protect the MIM structure against humidity and contaminant from outside to prevent degradation of the MIM structure over time. Further, the protective films 102, 106 may include the first protective film 106 which is disposed to cover the MIM structure and through which the intermediate electrodes 107 extend and the second protective film 102 constituted by a protective film other than the first protective film 106. One of the intermediate electrodes 107 may extend from the first internal electrode 103 through the first protective film 106 to the interface between the first protective film 106 and the joining resin 108 and further extend along the interface toward one of the end surfaces of the thin film capacitor to electrically connect with one of the external electrodes 109, 111; and the other of the intermediate electrodes 107 may extend from the internal electrode 105 through the first protective film 106 to the interface between the first protective film 106 and the joining resin 108 and further extend along the interface toward the other of the end surfaces of the thin film capacitor to electrically connect with the other of the external electrodes 109, 111. The joining resin may preferably cover at least part of the surface of the protective film other than the part covered with the first external electrode and the second external electrode. Although these drawings show that each of the thin film capacitors includes only one MIM structure, it may also be possible that a plurality of MIM structures are stacked together. When a plurality of MIM structures are stacked together, an internal electrode of one MIM structure can also serve as an internal electrode of another MIM structure. The thickness of the MIM structure can be appropriately selected in accordance with the capacitance and required specifications such as resisting pressure. The multi-layer structure of the laminated thin film capacitor of the present invention may be made by the above operations. As described in FIGS. 14(a), 14(b) and 14(c), the direction of stacking the thin film capacitors can be changed desirably. There is less possibility of occurrence of stresses and warp in such laminated thin film capacitors as shown in particularly FIGS. 14(a) and 14(c), wherein the principal surfaces of the plurality of thin film capacitors on which intermediate electrodes 107 extend and the principal surfaces on which no intermediate electrodes 107 extend are arranged symmetrically with respect to the direction of stacking, or in other words, the thin film capacitors may have directionality since the internal structure thereof is asymmetric in the direction of stacking, and the symmetrical arrangement may include an even number of thin film capacitors constituted by the same number of positively oriented ones and oppositely oriented ones (if an even number of thin film capacitors are stacked together), or the symmetrical arrangement may include one thin film capacitor and an even number of thin film capacitors constituted by the same number of positively oriented ones and oppositely oriented ones (if an odd number of thin film capacitors are stacked together). As described above, the number of the thin film capacitors may be two or larger. In this case, the thin film capacitors can be stacked together via the joining resin 108. The outermost thin film capacitors in a complete laminated thin film capacitor may preferably be covered with the second protective film 102. If three or more thin film capacitors are stacked together, the second protective films 102 other than those at the outside surface of the laminated thin film capacitor may be inside the laminated thin film capacitor and thus may be eliminated since the joining resin can provide protection instead. In this case, the costs for the eliminated second protective films 102 can be reduced, as well as the thickness thereof.

The laminated thin film capacitors may include first and second external electrodes. In FIG. 8(a), the first and second external electrodes 109 may be disposed on a pair of end surfaces extending in the direction orthogonal to the principal surfaces of the protective films 102, 106. As shown in FIG. 8(b), one of the intermediate electrodes 107 may extend toward one of the end surfaces of the protective films 102, 106, and the other of the intermediate electrodes 107 may extend toward the other of the end surfaces of the protective films 102, 106. In the drawing, the intermediate electrodes 107, extending toward the end surfaces of the protective films 102, 106, may not be exposed from the end surfaces but may preferably be exposed from the end surfaces. Simultaneously, a part of the joining resin 108 may contact the intermediate electrode 107, and the other part of the joining resin 108 may contact the protective layer. Each of the first and second internal electrodes 103, 105 may connect with one of the external electrodes 109 via one of the intermediate electrodes 107.

The joining resin 108 can absorb various mechanical stresses imparted on the laminated thin film capacitor of the present invention.

In the laminated thin film capacitor of the present invention, the thicknesses of the protective films and the thickness of the MIM structure are not particularly limited. The thickness of the protective film 106 may be 4 μm or smaller and may preferably be as small as possible, and the thickness of the thin film capacitor may also preferably be as small as possible.

Thus, in the laminated thin film capacitor of the present invention, the first external electrode may be connected with the first internal electrode via the first intermediate electrode, and the second external electrode may be connected with the second internal electrode via the second intermediate electrode. When a voltage is applied across the first and second external electrodes, the capacitor including the MIM structure having the dielectric body 104 placed between the first and second internal electrodes 103, 105 may perform the action thereof. The laminated thin film capacitor of the present invention can be finally removed from the supporting substrates. With no supporting substrates, the laminated thin film capacitors can be mounted with low profiles without discriminating the top and bottom surfaces of the device. As described above, in the present invention, it may also be possible that one or both of the supporting substrates of the thin film capacitors at both ends of the laminate remain unremoved. If the supporting substrates remain unremoved, the low profiles of the components cannot be achieved, but on the other hand, the component can have increased strength.

As described above, the laminated thin film capacitor can include three or more thin film capacitors stacked together in accordance with the required capacitance. In the present invention, it may be possible to form a low-profile device having a thickness of 100 μm or smaller.

Next, a circuit having mounted thereon the laminated thin film capacitor according to an embodiment of the present invention will now be described.

A circuit having mounted thereon the laminated thin film capacitor of the present invention may be an embodiment of the present invention. A circuit having mounted thereon the laminated thin film capacitor of the present invention may be, for example, a power supply circuit for an IC. There is particularly a power supply circuit used as a bypass capacitor under the main part of an IC, taking advantage of the height of the laminated thin film capacitor being smaller than that of solder bumps in the IC. The present invention may be applied to any circuits having the laminated thin film capacitor mounted thereon other than a power supply circuit.

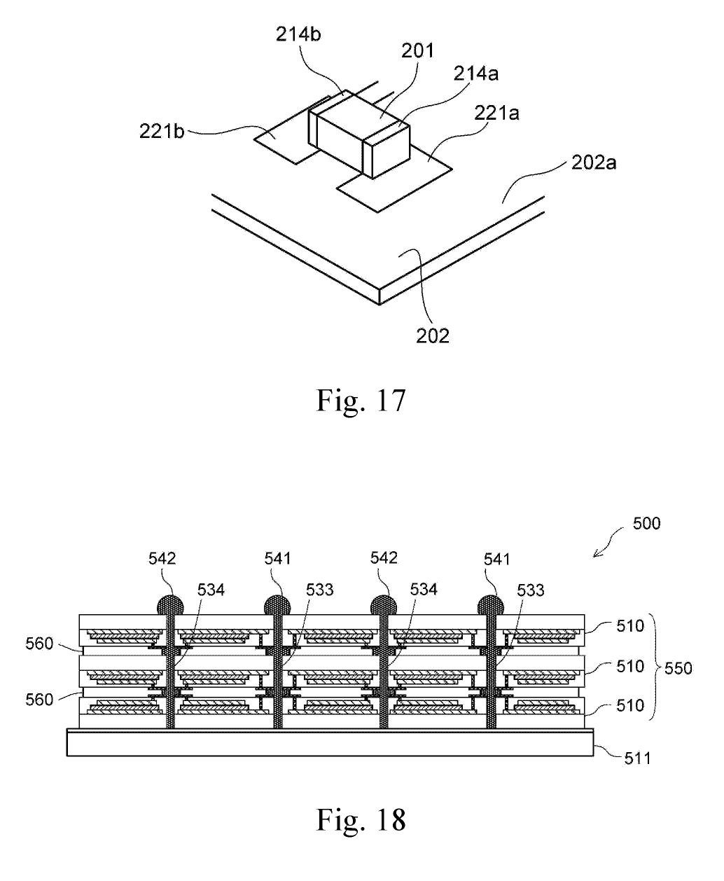

FIG. 17 is a perspective view of an example of the laminated thin film capacitor of the present invention mounted on a circuit board.

In FIG. 17, the reference numeral 201 denotes the laminate thin film capacitor of the present invention. The number of the laminated thin film capacitors stacked together may not be particularly limited but may be two or more. The shape of the external electrodes may also be not particularly limited.

The external electrodes 214a, 214b may be constituted by thin metal films made of a sintered metal paste as may be the internal electrodes. The metal paste may be, for example, a noble metal material such as Pd or Ag—Pd but may preferably be appropriately selected from Ag, Cu, Ni, Al, and Zn in view of the costs. Solder plating may be provided on the surface of the external electrodes for better solder wettability.

The reference numeral 202 denotes a circuit board which may herein be a multi-layer printed board but may also be other types of circuit boards. On the surface 202a of the circuit board 202, lands 221 may be formed for mounting the laminated thin film capacitor 201.

The first external electrode 214 of the laminated thin film capacitor 201 mounted on the surface 202a of the circuit board 202 may be conductively connected to one of the lands 221 by solder, and the second external electrode 214 may be conductively connected to the other of the lands 221.

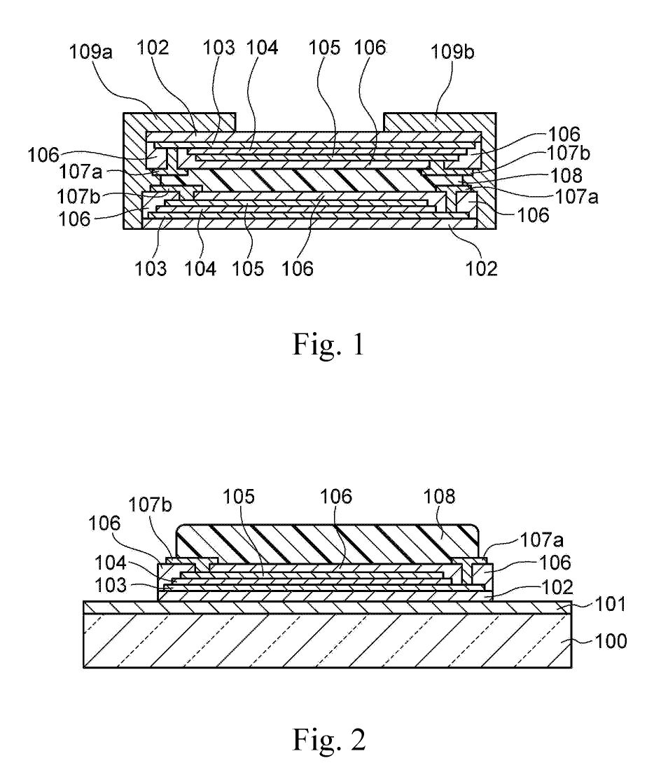

The laminated thin film capacitor disclosed in FIG. 1 of the '077 Publication, the net height of the laminated thin film capacitor from the bottom surface of the substrate 1 to the top surface of the external protective layer 34 is at least 30 μm.

With the thin film capacitor-mounted circuit of the present invention, the height of the main part of the circuit board including the components and solder thereon may be as small as 50 μm, while with the conventional laminated ceramic capacitor, the height of the main part of the circuit board including the component and solder thereon is 100 μm or larger. Thus, the apparatuses including a circuit board can be made compact and low-profile.

### Second Embodiment

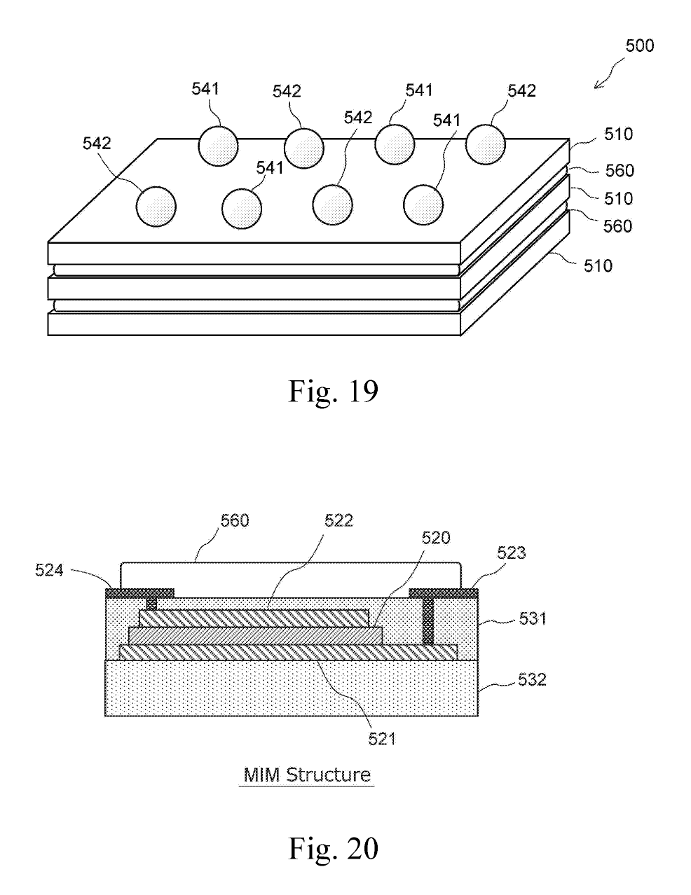

FIG. 18 is a schematic sectional view of a laminated thin film capacitor 500 according to the second embodiment of the present invention. FIG. 19 is an external perspective view of the laminated thin film capacitor 500. As with the first embodiment, the laminated thin film capacitor 500 according to the second embodiment may have a multi-layer structure of a plurality of thin film capacitors including a MIM structure. The laminated thin film capacitor 500 shown in FIGS. 18 and 19 may include a laminate 550 constituted by three layers of thin film capacitors 510, and each of the thin film capacitors 510 may include one MIM structure.

FIG. 20 shows an example of schematic sectional view of the MIM structure. As in the first embodiment, the MIM structure may include a dielectric body 520, a first internal electrode layer 521 disposed on one of the principal surfaces of the dielectric body 520, and a second internal electrode layer 522 disposed on the other of the principal surfaces of the dielectric body 520. A single thin film capacitor 510 may include at least one MIM structure, a first intermediate electrode 523 electrically connecting with the first internal electrode layer 521, and a second intermediate electrode 524 electrically connecting with the second internal electrode layer 522.

The thin film capacitor 510 may include a first protective layer 531 and a second protective layer 532. The first intermediate electrode 523 may extend from the first internal electrode layer 521 through the first protective film layer 531 to an interface between the first protective film layer 531 and a joining resin 560. On the other hand, the second intermediate electrode 524 may extend from the second internal electrode layer 522 through the first protective film layer 531 to the interface between the first protective film layer 531 and the joining resin 560. The first intermediate electrode 523 may further extend along the interface between the first protective film layer 531 and the joining resin 560 toward one end of the MIM structure, and may electrically connect with a first connection electrode at the end surface of the first protective film layer 531. On the other hand, the second intermediate electrode 524 may extend along the interface between the first protective film layer 531 and the joining resin 560 toward the other end of the MIM structure, and may electrically connect with a second connection electrode at the end surface of the first protective film layer 531.

The first connection electrode and the second connection electrode may extend through the laminate including a plurality of layers (three layers in the present embodiment) of thin film capacitors 510 stacked together, along the direction of stacking. The first external conductor may electrically connect with the first connection electrode at the outermost layer portion of the laminate, and the second external conductor may electrically connect with the second connection electrode at the outermost layer portion of the laminate.

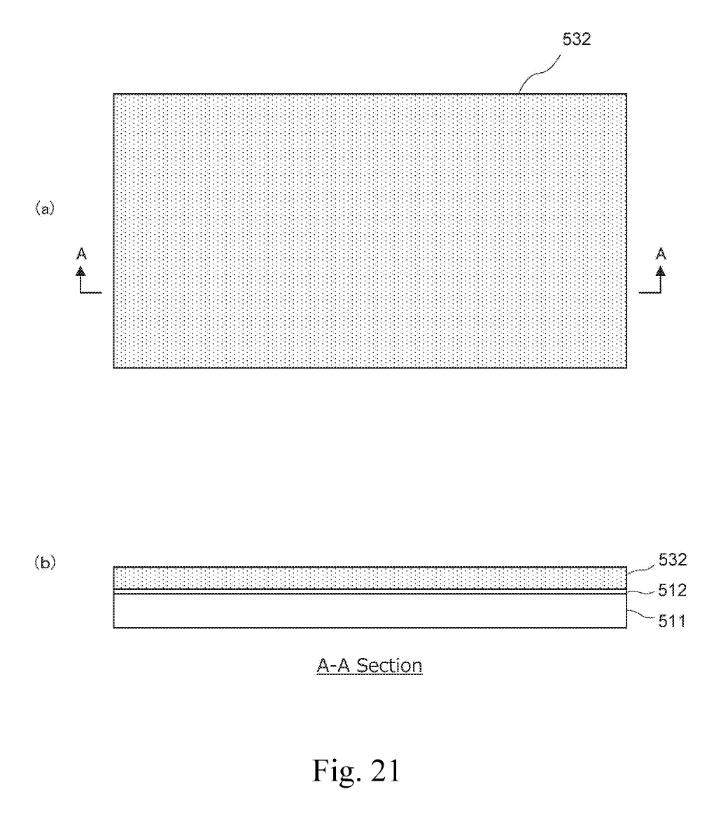

The fabrication method of the laminated thin film capacitor 500 will now be described. First, the process of fabricating a single thin film capacitor 510 will now be described with reference to FIGS. 21 to 29. The dielectric layer 520 and the electrode layers 521, 522, 523, 524 included in the thin film capacitor 510 may be formed by vacuum deposition (PVD, CVD) or sputtering.

First, a removal layer 512 may be formed on the supporting substrate 511, as shown in FIG. 21. The supporting substrate 511 may be, e.g., a Si substrate having a high smoothness and a heat resistance against the heat imparted during the capacitor fabrication process. If laser removal is employed in a later operation, substrates that transmit laser such as sapphire or quartz may be suitable.

The material for the removal layer 512 may be selected in accordance with the removing technique used in the later operation. If, e.g., laser removal is used, a material that may be burned away by laser application (metals or oxides) may preferably be selected.

If the removal layer 512 will be eliminated by wet etching, a material that can serve as a sacrifice layer (to be eliminated later) may preferably be selected.

Next, the second protective film layer 532 may be formed on the top surface of the removal layer 512. The material for the second protective film layer 532 may be required not to be damaged in the capacitor fabrication process, and to ensure the reliability of the completed capacitor. The thickness of the second protective film layer 532 may preferably be 4 μm or smaller, or more preferably 1 μm or smaller. The materials that can be selected for the second protective film layer 532 may include inorganic materials such as SiO₂, SiN, Al₂O₃, and ZrO₂ and organic materials such as polyimide resins and benzocyclobutene (BCB) resins.

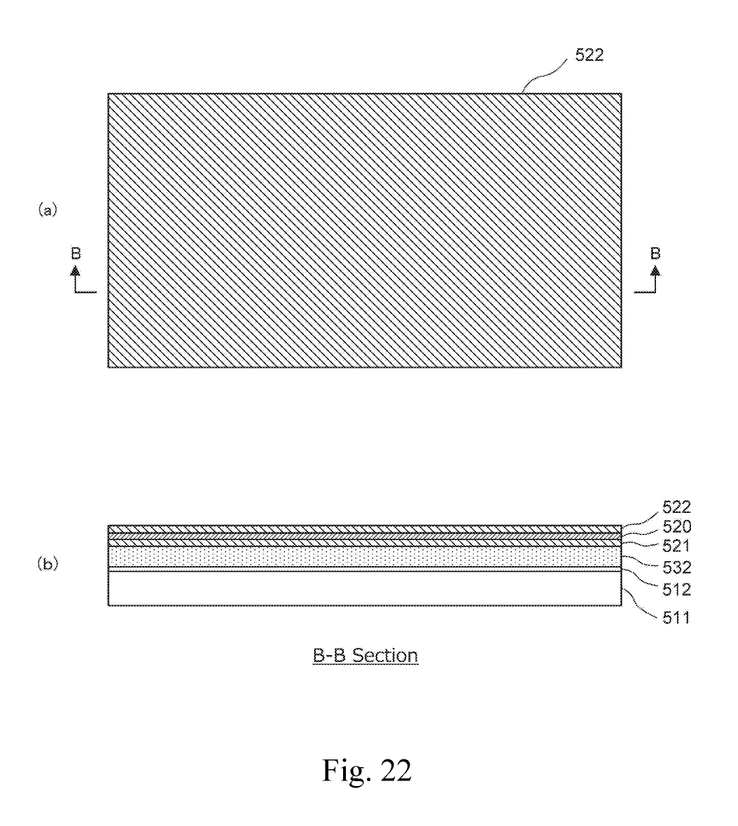

As shown in FIG. 22, the MIM structure including the first and second internal electrode layers 521, 522 and the dielectric layer 520 may be formed on the top surface of the second protective film layer 532. In the example shown in FIG. 22, the first internal electrode layer 521, the dielectric layer 520, and the second internal electrode layer 522 may be formed in this order.

The conductive materials that can be selected for the first and second internal electrode layers 521, 522 may include Pt, Ni, Pd, Cu, Al, etc. To reduce the leakage current value, it may be preferable to select a conductive material having a large work function such as Ni and Pt. If sputtering is used to form the dielectric layer in an oxygen atmosphere at 600° C. or higher, the conductive material used may preferably be Pt, which has less tendency to be oxidized. If atomic layer deposition (ALD) is used to form the dielectric layer at a low temperature, it may also be possible to use low-cost conductive materials such as Ni, Al Cu, etc.

The dielectric material for the dielectric layer 520 may be barium strontium titanate (BST), barium titanate (BT), strontium titanate (ST), Al₂O₃, ZrO₂, or other metal oxides. To obtain a capacitor having a large capacitance, it may be preferable to use a material having a large relative dielectric constant such as BST, BT, and ST. To obtain a capacitor having excellent temperature characteristics and DC bias characteristics, it may be possible to use a paraelectric material such as HfO₂.

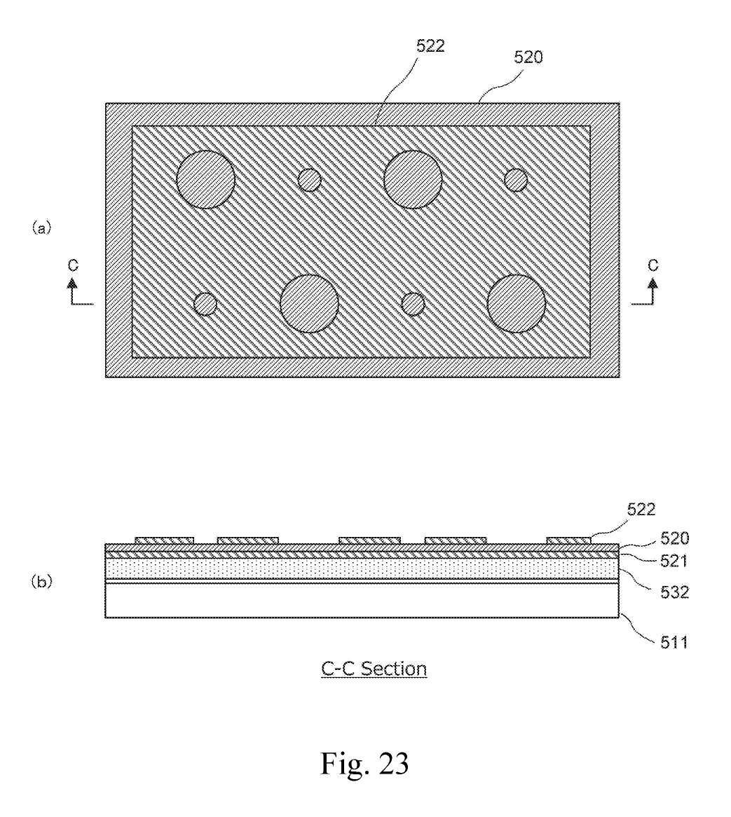

Next, as shown in FIG. 23, the second internal electrode layer 522 may be etched. The etching operation may be dry etching, wet etching, etc. or may be performed by metal masking.

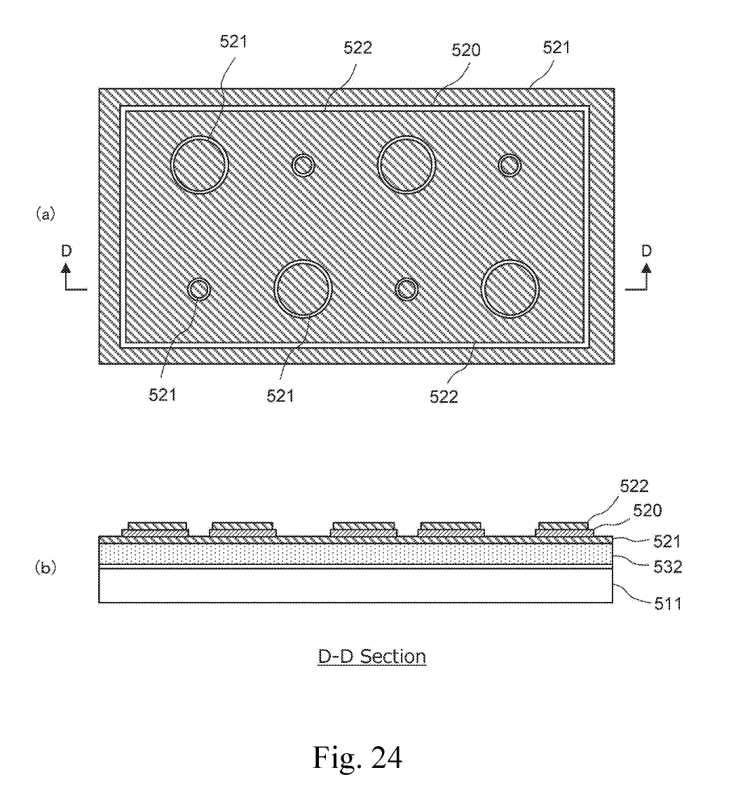

Next, as shown in FIG. 24, the dielectric layer 520 may be etched. The etching operation may be dry etching, wet etching, etc. or may be performed by metal masking.

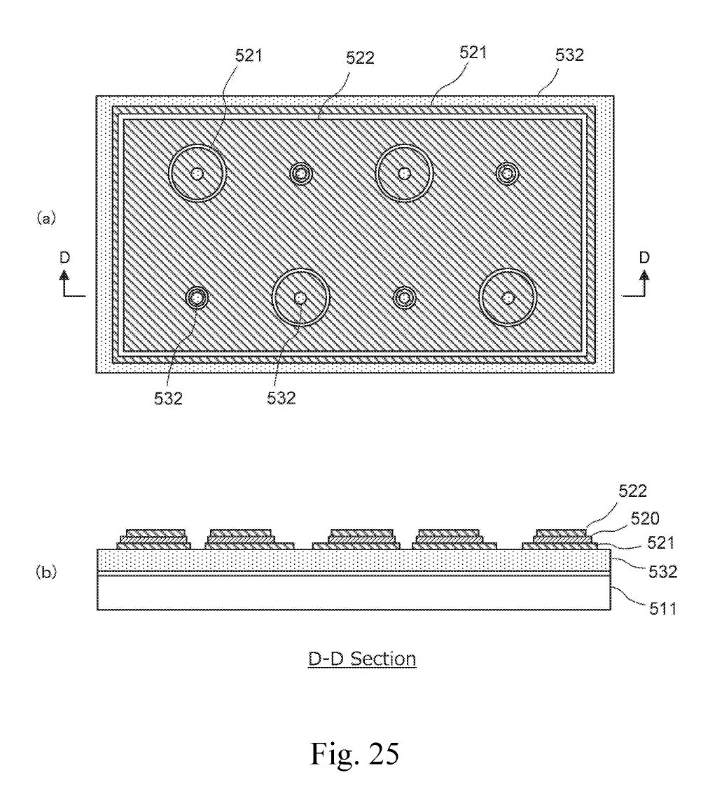

Next, as shown in FIG. 25, the first internal electrode layer 521 may be etched. The etching operation may be dry etching, wet etching, etc. or may be performed by metal masking.

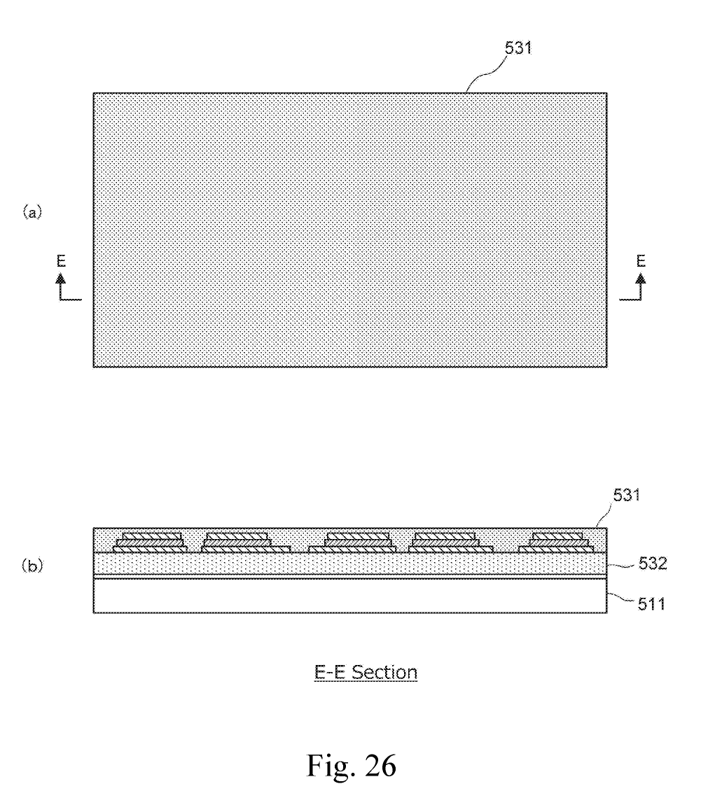

Next, as shown in FIG. 26, the first protective film layer 531 may be formed to cover the entirety of the MIM structure. The material for the first protective film layer 531 may preferably be the same as for the second protective film layer 532 in order to equalize the mechanical behaviors such as the coefficient of thermal contraction and reduce internal residual stresses.

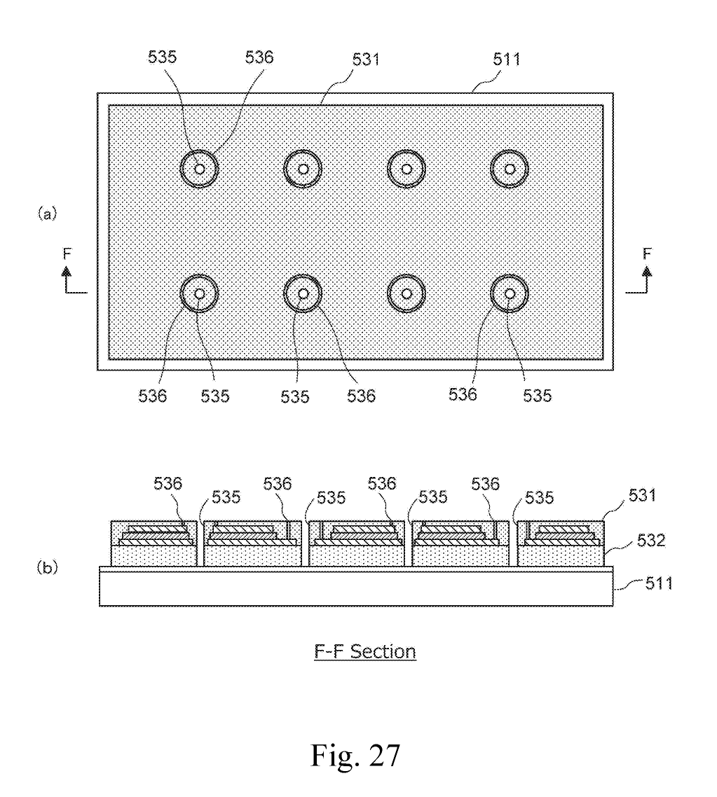

Next, as shown in FIG. 27, though-holes 535 may be etched to pierce the first protective film layer 531 and the second protective film layer 532 so as to form the connection electrodes 533, 534. Simultaneously, annular grooves 536 may be etched around the through-holes 535 in the first protective film layer 531 to form the intermediate electrodes 523, 524. The etching operation may be dry etching, wet etching, photo etching, etc. If the first and second protective film layers 531, 532 are formed of organic materials, a photosensitive material may be used for photoetching to reduce the processing load.

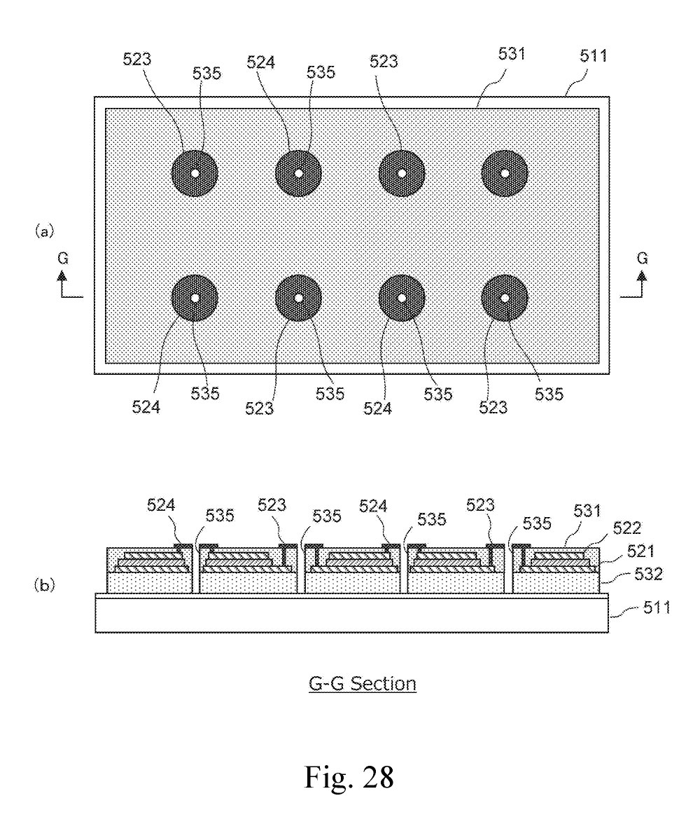

Then, as shown in FIG. 28, intermediate electrode conductors may be formed in the annular grooves 536 etched in the first protective film layer 531. Further, the first and second intermediate electrodes 523, 524 may be formed to a circular shape on the top surface of the first protective film layer 531 (in other words, on the surface opposite to the supporting substrate 511) around the through-holes 535. The conductive materials that can be selected for the first and second intermediate electrodes 523, 524 may be the same as for the first and second internal electrode layers 521, 522.

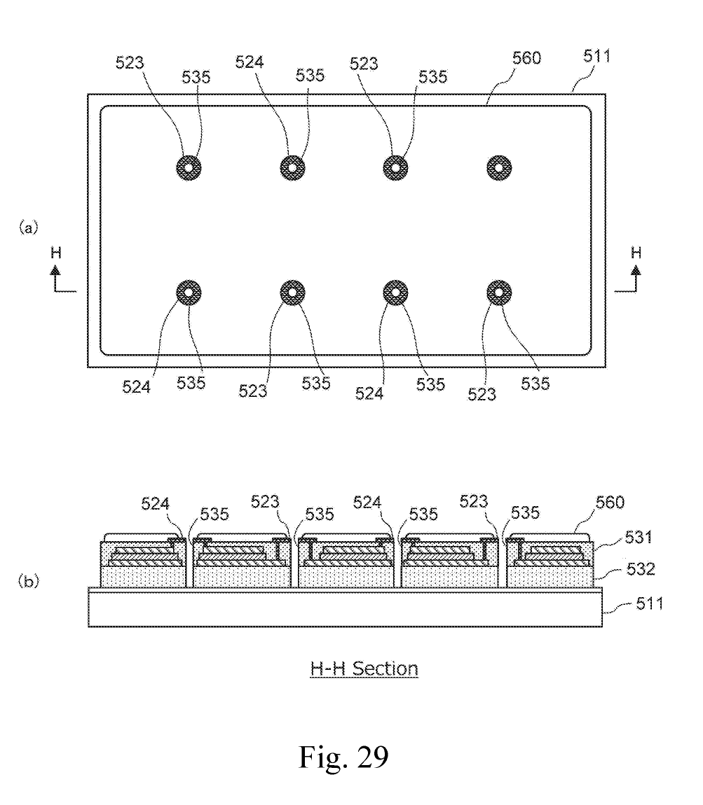

Next, as shown in FIG. 29, joining layers 560 may be formed by patterning a resin on the top surface of the first protective film layer 531 outside the first and second intermediate electrodes 523, 524. This operation may be performed by applying a photolithography technique. First, an uncured photosensitive resin made of phenol-based polymer, polyimide, BCB, etc. may be applied onto the top surface of the first protective film layer 531. Then, a photomask may be used to expose a region other than the central portions of the first and second intermediate electrodes 523, 524 so as to cure the resin to the B-stage state. The light source for exposure may be appropriately selected from semiconductor laser, G-line, H-line, and I-line of a high-pressure mercury-vapor lamp, KrF excimer laser, ArF excimer laser, F2 excimer laser, metal halide lamp, ultraviolet rays, extreme ultraviolet rays, electron beam, etc. Finally, the resin may be removed from the first and second intermediate electrodes. As in the example shown in FIG. 29, it may be preferable that the first and second intermediate electrodes 523, 524 are covered with the resin of the joining layer 560 at only the peripheries thereof.

The joining layer 560 may be required to have such a thickness as to satisfy the requirement for the joining operation, and the thickness may preferably be 5 μm or smaller, or more preferably 2 μm or smaller for lower profiles.

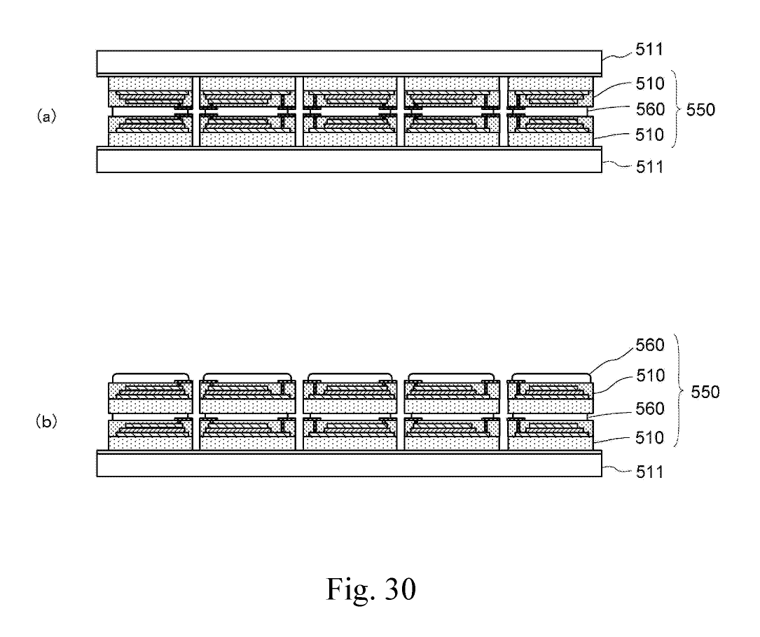

A plurality of thin film capacitors 510 thus fabricated may be joined together to form a multi-layer capacitor laminate 550. The method for joining the thin film capacitors 510 may be to (1) oppose the joining layers of two thin film capacitors to each other to form a symmetrical arrangement (FIG. 30(a)) or (2) oppose the second protective film layer of one thin film capacitor from which the supporting substrate has been removed to the joining layer of the other thin film capacitor to orient these thin film capacitors in the same direction (FIG. 30(b)). In either method, the joining resin 560 may be fused for bonding by thermal curing so as to join the thin film capacitors 510. The supporting substrate 511 may be removed by laser application, etc.

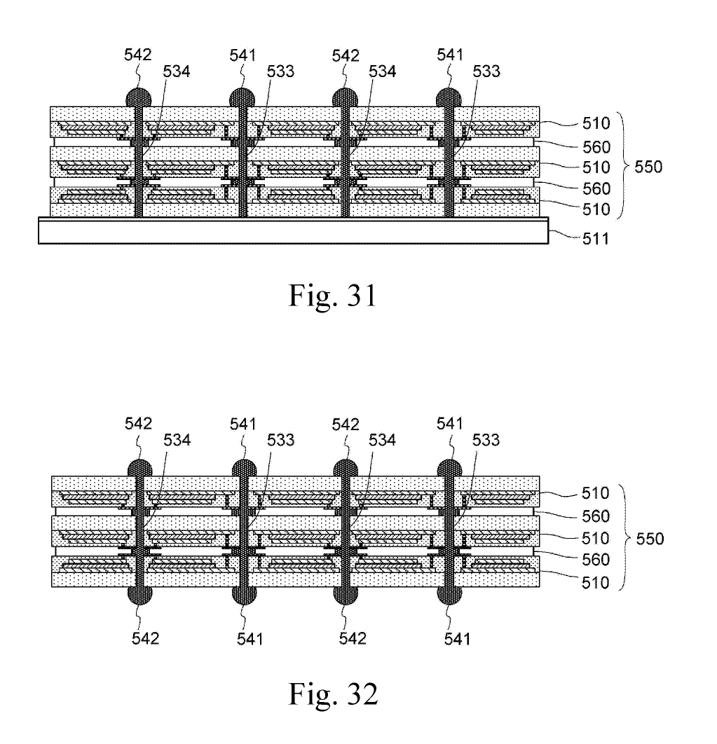

As shown in FIG. 31, the first and second connection electrodes 533, 534 may be formed by filling a conductor into the through-holes 535 extending through the capacitor laminate 550. For example, a solder paste may be printed on the top surface of the laminate and melted by reflow, so as to withdraw the conductor into the through-holes 535 by the capillary action. Alternatively, a metal (e.g., Cu) seed layer may be formed in the through-holes 535 by using, e.g., an ALD apparatus having excellent coating performance, and then a metal may be filled by plating (e.g., plating with Cu or double layer plating with Cu and Sn). The diameters of the first and second connection electrodes 533, 534 may be 3 to 50 μm.

The first connection electrodes and the second connection electrodes 533, 534 may be formed substantially in parallel with each other so as to extend through the laminate 550 including a plurality of thin film capacitors 510. Therefore, equivalent series inductance (ESL) can be reduced.

Further, solder balls may be placed on the metal filled into the through-holes 535 so as to form bumps of the first external conductors 541 electrically connecting with the first connection electrodes 533 and the second external conductors 542 electrically connecting with the second connection electrodes 534. These external electrodes 541, 542 may be formed as flat electrodes by printing

As in the variation example shown in FIG. 32, it may also be possible to remove the underlying supporting substrate and form the external electrodes 541, 542 on the undermost second protective film layer. Such a laminated thin film capacitor having multi-terminal electrode structure on both surfaces can be effectively used in an embedded circuit board.

The laminated thin film capacitor 500 according to the second embodiment may have a larger capacitance produced by lamination along with the following effects that were difficult to obtain by conventional techniques.

(1) The first and second connection electrodes 533, 534 extending through a laminate of a plurality of thin film capacitors 510 and electrically connecting these thin film capacitors may be formed substantially in parallel with each other along the lamination direction of the laminate. Thus, multi-terminal electrode structure for lower ESL can be achieved.
(2) Even in the multi-terminal structure for lower ESL, the thin film capacitors 510 having similar capacitances can be stacked together to increase the capacitance efficiently.
(3) If the thin film capacitors 510 have almost the same capacitance (with variation of ±5% or smaller), the self-resonant frequency may have a sharp waveform, not a multi-stage waveform, producing stable characteristics.
(4) The regions of the intermediate electrodes 523, 524 connecting with the external conductors 541, 542 and the internal electrodes 521, 522 connecting with the intermediate electrodes 523, 524 may be formed in the planes orthogonal to the lamination direction, not the planes along the side surfaces of the thin films, thereby suppressing the contact resistance. Therefore, ESR can be reduced.
(5) The intermediate electrodes 523, 524, etc. may reduce internal stresses imparted on the MIM structures caused by connection, thereby increasing the reliability and the life of the laminated thin film capacitor 500.

What is claimed is:

1. A laminated thin film capacitor comprising:
a plurality of thin film capacitors stacked together via a joining resin to form a laminate; and
a first external electrode and a second external electrode electrically connected to the plurality of thin film capacitors,
wherein each of the plurality of thin film capacitors includes:
at least one MIM structure including a dielectric body, a first internal electrode disposed on one principal surface of the dielectric body, and a second internal electrode disposed on the other principal surface of the dielectric body;
a first intermediate electrode electrically connecting the first internal electrode and the first external electrode; and
a second intermediate electrode electrically connecting the second internal electrode and the second external electrode.

2. A laminated thin film capacitor comprising:
a plurality of thin film capacitors stacked together via a joining resin to form a laminate; and
a first external conductor and a second external conductor electrically connected to the plurality of thin film capacitors,
wherein each of the plurality of thin film capacitors includes:
at least one MIM structure including a dielectric body, a first internal electrode disposed on one principal surface of the dielectric body, and a second internal electrode disposed on the other principal surface of the dielectric body;
a first intermediate electrode electrically connecting the first internal electrode and the first external conductor; and
a second intermediate electrode electrically connecting the second internal electrode and the second external conductor.

3. The laminated thin film capacitor of claim 2, wherein
the plurality of thin film capacitors are electrically connected to each other via a first connection electrode and a second connection electrode extending through the laminate,
each of the plurality of thin film capacitors has the first intermediate electrode thereof electrically connected to the first connection electrode,
each of the plurality of thin film capacitors has the second intermediate electrode thereof electrically connected to the second connection electrode,
the first external conductor is electrically connected to the first connection electrode at an outermost layer of the laminate, and
the second external conductor is electrically connected to the second connection electrode at the outermost layer of the laminate.

4. The laminated thin film capacitor of claim 3, wherein the first connection electrode and the second connection electrode are formed substantially in parallel with each other along a lamination direction of the laminate.

5. The laminated thin film capacitor of claim 1, wherein
each of the plurality of thin film capacitors further includes a protective film disposed to cover the MIM structure,
the first intermediate electrode extends from the first internal electrode through the protective film to an interface between the protective film and the joining resin and extends along the interface toward one end surface of the thin film capacitor so as to be electrically connected to the first external electrode, and
the second intermediate electrode extends from the second internal electrode through the protective film to an interface between the protective film and the joining resin and extends along the interface toward the other end surface of the thin film capacitor so as to be electrically connected to the second external electrode.

6. The laminated thin film capacitor of claim 3, wherein
each of the plurality of thin film capacitors further includes a protective film disposed to cover the MIM structure,
the first intermediate electrode extends from the first internal electrode through the protective film to an interface between the protective film and the joining resin and extends along the interface toward one end surface of the thin film capacitor so as to be electrically connected to the first connection electrode, and
the second intermediate electrode extends from the second internal electrode through the protective film to an interface between the protective film and the joining resin and extends along the interface toward the other end surface of the thin film capacitor so as to be electrically connected to the second connection electrode.

7. The laminated thin film capacitor of claim 5, wherein the first intermediate electrode and the second intermediate electrode extend to the interface with the same joining resin.

8. The laminated thin film capacitor of claim 5, wherein
the first intermediate electrode is exposed from one end surface of the protective film, and
the second intermediate electrode is exposed from the other end surface of the protective film.

9. The laminated thin film capacitor of claim 5, wherein the joining resin covers at least a part of a surface of the protective film other than a part covered with the first external electrode and the second external electrode.

10. The laminated thin film capacitor of claim 1, wherein each of the plurality of thin film capacitors has directionality caused by an internal structure thereof being asymmetric in a lamination direction, and the laminate includes an even number of thin film capacitors constituted by a same number of positively oriented ones and oppositely oriented ones.

11. The laminated thin film capacitor of claim 1, wherein each of the plurality of thin film capacitors has directionality caused by an internal structure thereof being asymmetric in a lamination direction, and the laminate includes one thin film capacitor and an even number of thin film capacitors constituted by a same number of positively oriented ones and oppositely oriented ones.

12. The laminated thin film capacitor of claim 1, wherein at least one principal surface of the laminated thin film capacitor has a supporting substrate.

13. The laminated thin film capacitor of claim 1, wherein neither principal surface of the laminated thin film capacitor has a supporting substrate.

14. A circuit comprising: a mounting surface; first and second wiring provided on the mounting surface; and the laminated thin film capacitor of claim 2 mounted on the mounting surface, wherein the first and second external conductors of the laminated thin film capacitors are electrically connected to the first and second wiring, respectively.

15. A printed circuit board including the laminated thin film capacitor of claim 1 mounted thereon.
